(19) United States
(12) Patent Application Publication
(10) Pub. No.: US 2021/0359185 A1
(43) Pub. Date: Nov. 18, 2021

(54) DEVICE INCLUDING VIAS AND METHOD AND MATERIAL FOR FABRICATING VIAS

(71) Applicant: Corning Incorporated, Corning, NY (US)

(72) Inventors: Sean Matthew Garner, Elmira, NY (US); Patrick Scott Leslie, Tucson, AZ (US); Barada Kanta Nayak, Painted Post, NY (US); Michael Lesley Sorensen, Waverly, NY (US); Rajesh Vaddi, Corning, NY (US)

(21) Appl. No.: 17/286,271

(22) PCT Filed: Oct. 9, 2019
(86) PCT No.: PCT/US2019/055343

§ 371 Date: Apr. 16, 2021

Related U.S. Application Data
(60) Provisional application No. 62/876,131, filed on Jul. 19, 2019.
(60) Provisional application No. 62/747,959, filed on Oct. 19, 2018.

(51) Int. Cl. H01L 33/62; H01L 33/00; H01L 33/44; H01L 25/16; B23K 26/55; B23K 26/16

(52) U.S. Cl. CPC H01L 33/62; H01L 33/0095; H01L 33/44; H01L 25/167; B23K 2103/54; B23K 26/16; H01L 2933/0066; H01L 2933/0025; B23K 26/55

(57) ABSTRACT

A device includes a glass substrate, a plurality of electronic components, a metallization layer, and a plurality of vias. The plurality of electronic components are on a first surface of the glass substrate. The metallization layer is on a second surface of the glass substrate opposite to the first surface. The plurality of vias extend through the glass substrate. At least one via is in electrical communication with an electronic component and the metallization layer.

This application claims the benefit of priority under 35 U.S.C. § 119 of U.S. Provisional Application Ser. No. 62/876,131 filed on Jul. 19, 2019 and U.S. Provisional Application Ser. No. 62/747,959 filed on Oct. 19, 2018, the content of each are relied upon and incorporated herein by reference in their entirety.

### BACKGROUND

### Field

The present disclosure relates generally to through glass vias. More particularly, it relates to laser formed through glass vias for electronic devices.

### Technical Background

Micro light emitting diode (microLED) displays may have a higher brightness and a higher contrast ratio compared to liquid crystal displays (LCDs) and organic light emitting diode (OLED) displays. There may be other benefits of microLED displays depending upon the specific application. To enable high resolution and large area displays, there is interest in fabricating microLED displays with active matrix backplanes based on Low Temperature PolySilicon (LTPS) or oxide thin-film transistors (TFTs). A display configuration may include top emitting microLED panels with driver boards located on the display backside. If these display panels are used in large area tiled display applications, electrical interconnections between the two substrate surfaces should be fabricated in a way that enables close tile-to-tile spacing (e.g., less than 100 micrometers spacing between tiles).

Metalized vias in a glass substrate may be used to electrically interconnect components on a first side of the glass substrate to components on a second side of the glass substrate. There are multiple methods for fabricating vias in glass substrates. These methods, however, are mainly focused on the fabrication of high quality vias, at high density, in thin glass (e.g., less than 0.3 millimeters), and on small substrate sizes (e.g., less than 300 millimeters). One method for fabricating vias utilizes a laser damage and multi-hour glass etch process. A via fabricated using the laser damage and multi-hour glass etch process has nearly vertical sidewalls. To enable utilization of existing large generation size display glass processing, the via should be fabricated in glass substrates having thicknesses greater than about 0.3 millimeters. Limiting the via aspect ratio to an approximate value of 5:1, the via diameter would be about 60 micrometers for a straight sidewall structure. This 60 micrometers diameter would take up significant space within a pixel layout. In addition, using via fabrication processes that have been optimized for interposer or other applications results in an over-designed via fabricated in a higher cost process. Lasers may be used to create through glass vias or micro-holes in glass. Direct laser ablation based micro-hole drilling, however, creates undesirable debris and also a rim around the micro-hole.

### SUMMARY

Some embodiments of the present disclosure relate to a device. The device includes a glass substrate, a plurality of electronic components, a metallization layer, and a plurality of vias. The plurality of electronic components are on a first surface of the glass substrate. The metallization layer is on a second surface of the glass substrate opposite to the first surface. The plurality of vias extend through the glass substrate. At least one via is in electrical communication with an electronic component and the metallization layer. At least one via includes a first diameter at the first surface and a second diameter greater than the first diameter at the second surface such that a ratio of the second diameter to the first diameter is greater than 1.5:1.

Yet other embodiments of the present disclosure relate to a method for fabricating vias. The method includes applying a first gel layer over a first surface of a glass substrate. The method includes laser ablating the glass substrate to form a via hole through the glass substrate such that debris from the laser ablating is trapped in the first gel layer. The method includes removing the first gel layer from the first surface.

Yet other embodiments of the present disclosure relate to material for collecting debris due to laser ablation. The material includes a first solution and a second solution. The first solution includes 5% to 10% PolyVinyl Alcohol (PVA) in water by weight. The second solution includes 1% to 10% Sodium Tetraborate in water by weight.

Yet other embodiments of the present disclosure relate to a device. The device includes a glass substrate, a plurality of electronic components, a metallization layer, and a plurality of vias. The plurality of electronic components are on a first surface of the glass substrate. The metallization layer is on a second surface of the glass substrate opposite to the first surface. The plurality of vias extend through the glass substrate. At least one via is in electrical communication with an electronic component and the metallization layer. At least one via is at least partially filled with an insulating, conductive, or semi-conductive material.

The methods and materials disclosed herein may be used to form devices including substantially debrisless and substantially rimless laser-formed through glass vias. Via holes may be fabricated quickly and cost effectively using laser ablation and a gel layer to collect debris and to prevent rim formation around the via holes. Accordingly, the via holes may be formed without the use of toxic chemicals typically used for vias formed using a laser damage and etching process. Via holes of different shapes and sizes may be formed in the same substrate. Via holes of a wide range of taper angles may also be formed. In addition, the via holes may be formed before or after the fabrication of other components (e.g., electronic components) on the substrate. The gel layer used to collect the debris and to minimize rim formation during the laser ablating may be reused.

Additional features and advantages will be set forth in the detailed description which follows, and in part will be readily apparent to those skilled in the art from that description or recognized by practicing the embodiments as described herein, including the detailed description which follows, the claims, as well as the appended drawings.

It is to be understood that both the foregoing general description and the following detailed description are merely exemplary, and are intended to provide an overview or framework to understanding the nature and character of the claims. The accompanying drawings are included to provide a further understanding, and are incorporated in and constitute a part of this specification. The drawings illustrate one or more embodiment(s), and together with the description serve to explain principles and operation of the various embodiments.

### BRIEF DESCRIPTION OF THE DRAWINGS

FIG. 1 is a cross-sectional view of an exemplary device including a plurality of vias;

FIGS. 2A-2C are cross-sectional views of exemplary via holes having linear sidewalls;

FIGS. 2D, 3A and 3B are cross-sectional views of exemplary via holes having curved sidewalls;

FIGS. 4A-4C are cross-sectional views illustrating an exemplary method for fabricating via holes using a gel layer on one side of a glass substrate;

FIGS. 5A-5C are cross-sectional views illustrating an exemplary method for fabricating via holes using a gel layer on both sides of a glass substrate;

FIGS. 6A and 6B are cross-sectional views illustrating an exemplary method for fabricating components on a glass substrate prior to applying a gel layer on both sides of the glass substrate;

FIG. 7A is a cross-sectional view of an exemplary material for collecting debris due to laser ablation prior to use; and

FIG. 7B is a cross-sectional view of the exemplary material of FIG. 7A after use.

### DETAILED DESCRIPTION

Reference will now be made in detail to embodiments of the present disclosure, examples of which are illustrated in the accompanying drawings. Whenever possible, the same reference numerals will be used throughout the drawings to refer to the same or like parts. However, this disclosure may be embodied in many different forms and should not be construed as limited to the embodiments set forth herein.

Ranges can be expressed herein as from “about” one particular value, and/or to “about” another particular value. When such a range is expressed, another embodiment includes from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

Directional terms as used herein—for example up, down, right, left, front, back, top, bottom, vertical, horizontal—are made only with reference to the figures as drawn and are not intended to imply absolute orientation.

Unless otherwise expressly stated, it is in no way intended that any method set forth herein be construed as requiring that its steps be performed in a specific order, nor that with any apparatus, specific orientations be required. Accordingly, where a method claim does not actually recite an order to be followed by its steps, or that any apparatus claim does not actually recite an order or orientation to individual components, or it is not otherwise specifically stated in the claims or description that the steps are to be limited to a specific order, or that a specific order or orientation to components of an apparatus is not recited, it is in no way intended that an order or orientation be inferred, in any respect. This holds for any possible non-express basis for interpretation, including: matters of logic with respect to arrangement of steps, operational flow, order of components, or orientation of components; plain meaning derived from grammatical organization or punctuation, and; the number or type of embodiments described in the specification.

As used herein, the singular forms “a,” “an,” and “the” include plural references unless the context clearly dictates otherwise. Thus, for example, reference to “a” component includes aspects having two or more such components, unless the context clearly indicates otherwise.

Compared to interposer or other applications, in display applications the substrates may be larger, the glass may be thicker, relatively few vias may be used, and some via requirements may be relaxed. For example, for glass substrates with edge dimensions greater than about 100, 200, 300, 400, 500, 700, 1000, or 2000 millimeters; the glass thickness may be less than about 2, 1, 0.7, 0.6, 0.5, 0.4, or 0.3 millimeters. These combinations of glass substrate edge dimensions and glass thicknesses may increase restrictions on the via diameter and increase the challenge of placement within a pixel layout. Although the substrate is described as glass, in certain exemplary embodiments the substrate may be a ceramic or glass-ceramic material. In other embodiments, the substrate may include multiple layers of substantially similar or different materials.

Accordingly, disclosed herein is a glass electronics substrate, which may be used for a display. As display resolution increases, there is less area within a pixel to accommodate emitters, TFTs, conductor lines, and other components. Because of this, the size of the components within a pixel should be minimized. In addition, for top emission tiled displays, an electrical interconnection may be used between the substrate top surface and back surface. Using top emitting microLED displays as an example, the microLEDs and TFT matrix (e.g., LTPS, oxide, aSi, or organic semiconductor) on top of the glass substrate should be electrically interconnected with the driver board located under the glass substrate. Electrical vias may provide this interconnection ability. These vias should have a minimum size and a highly registered placement to fit within the crowded layout of a high resolution display pixel. A typical pixel may have a less than about 1 millimeter or less than about 700, 500, 400, 300, or 200 micrometers pixel pitch in either the vertical or horizontal directions. Although a TFT active matrix is specifically mentioned, the need for a small diameter high-registration via also applies to passive matrix and direct-driver configurations. Display applications or other applications using the vias and via fabrication processes disclosed herein result in faster throughput and lower cost than previous fabrication processes. Although microLED displays are discussed as an example, other applications may include liquid crystal displays, OLED displays, and non-display devices.

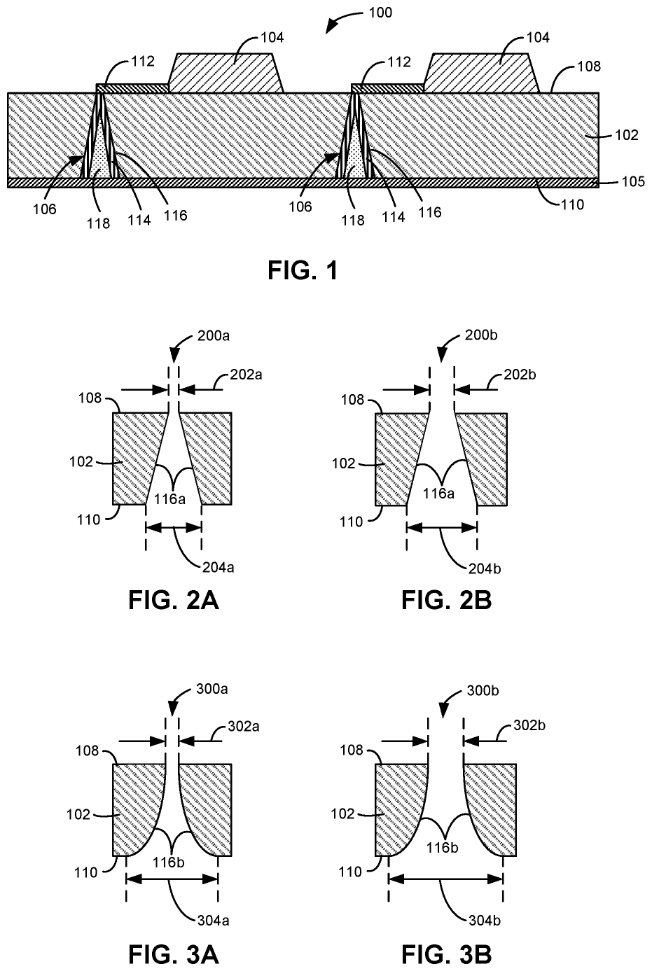

Referring now to FIG. 1, a cross-sectional view of an exemplary device 100 is depicted. Device 100 includes a glass substrate 102, a plurality of electronic components 104, a metallization layer 105, and a plurality of vias 106. In certain exemplary embodiments, device 100 is a display device and the plurality of electronic components 104 includes a plurality of thin-film transistors. In other embodiments, device 100 is a non-display device and electronic components in general can exist on both substrate surfaces. The plurality of electronic components 104 are on a first surface 108 of the glass substrate 102. The metallization layer 105 is on a second surface 110 of the glass substrate 102 opposite to the first surface 108. The plurality of vias 106 extend through the glass substrate 102. Each via 106 is in electrical communication with the metallization layer 105 and an electronic component 104 through a conductor 112. In other embodiments, vias 106 may be in direct physical contact with electronic components 104. There may also be via structures present that are not in electrical communication with a metallization layer. The vias may be within about a 500, 200, 100, 50, 20, or 10 micrometers distance from the nearest electrical component on the surface. Each via 106 includes a first diameter at the first surface 108 and a second diameter greater than the first diameter at the second surface 110 as will be described in more detail below with reference to FIGS. 2A-3B. Each of the vias 106 may be tapered from the second surface 110 to the first surface 108. Therefore, each via 106 has a smaller diameter at the first surface 108 than at the second surface 110. The smaller diameter of each via 106 at the first surface 108 allows the spacing between electronic components 104 to be reduced compared to vias that are not tapered. In this way, vias 106 may be precisely placed within a crowded high-resolution display backplane.

Glass substrate 102 may, for example, have a thickness between the first surface 108 and the second surface 110 of about 0.3 millimeters or greater. Each of the vias 106 may include linear sidewalls 116 between the first surface 108 and the second surface 110. Each of the vias 106 may include a conformal conductive layer 114 (e.g., Cu) on sidewalls 116 of the via. The conformal conductive layer 114 may form a cone shape that is pinched off at first surface 108. The conformal conductive layer 114 may enable compatibility with high temperature device processing by reducing the effects of the differential thermal expansion of the conductive material 114 and the glass substrate 102. In other embodiments, each via 106 may be fully filled with a conductive material.

The conformal conductive layer 114 of each via 106 may be able to survive higher temperature excursions without the failures observed with vias fully filled with a conductive material. For example, fully filled vias may suffer issues of stress cracking in the glass around the via and pistoning of the conductive material out of the via. This is due to the thermal expansion mismatch between the conductive material and the surrounding glass. If the via is filled conformally and pinched off at one end, the via may be able to survive the thermal excursions, for example greater than about 300, 400, 500, or 600 degrees Celsius. The conformal conductive layer 114 of each via 106 may have a thickness less than about 50, 20, 10, 5, 2, or 1 micrometers on the sidewalls 116 of each via.

In certain exemplary embodiments, each of the vias 106 may be filled with a material 118 within the conformal conductive layer 114 on the sidewalls 116 of each via. Whether insulating, conductive, or semi-conductive, the material 118 may also have a thermal expansion coefficient greater than about 20, 15, 10, or 5 parts per million per degree Celsius. The material 118 filling each via 106 may minimize process contamination, provide mechanical support, or provide other effects. For example, a sol-gel material may be used for material 118. The sol-gel material may be compatible with LTPS, oxide, aSi, or organic TFT processing. The sol-gel material may also survive thermal excursions greater than about 300, 400, 500, or 600 degrees Celsius. In certain exemplary embodiments, the material 118 may not completely fill the via as shown in FIG. 1. By volume, the material 118 between the conformal conductive layer 114 on the sidewalls 116 of each via may fill the opening by greater than about 10, 20, 50, 80, 90, 95, or 99 percent. The material 118 may also extend beyond the surface opening of the via. Additional suitable materials 118 may also be used including, but not limited to glass, glass ceramic, or other suitable materials having a thermal expansion coefficient less than, greater than, or equal to the adjacent substrate 102.

FIGS. 2A and 2B are cross-sectional views of exemplary via holes 200a and 200b, respectively. Via holes 200a and 200b are each formed through a glass substrate 102 including a first surface 108 and a second surface 110. Via holes 200a and 200b are tapered from the second surface 110 to the first surface 108 and include linear sidewalls 116a between the first surface 108 and the second surface 110. Overall, via holes 200a and 200b may have a frustum shape. Via hole 200a includes a first diameter 202a at the first surface 108 and a second diameter 204a greater than the first diameter 202a at the second surface 110. Likewise, via hole 200b includes a first diameter 202b at the first surface 108 and a second diameter 204b greater than the first diameter 202b at the second surface 110. For via hole 200b, however, first diameter 202b and second diameter 204b are greater than first diameter 202a and second diameter 204a of via hole 200a, respectively. In other embodiments, via holes 200a and 200b may have one diameter that is similar for each via hole and another diameter that is different for each via hole.

The first diameter 202a or 202b may be on a device side (i.e., first surface 108 of glass substrate 102) and, for example, be less than about 100, 50, 40, 30, 20, or 10 micrometers. In contrast, the second diameter 204a or 204b on the second side 110 of the glass substrate 110 may, for example, have a diameter of greater than about 50, 100, 150, or 200 micrometers. In certain embodiments, the ratio of the second diameters 204a and 204b to the first diameters 202a and 202b, respectively, may, for example, be greater than about 1.5:1, 2:1, 5:1, 10:1, or 15:1. The ratio of the thickness of glass substrate 102 to the first diameter 202a or 202b may, for example, be greater than about 2:1, 5:1, 10:1, 20:1, or 50:1. The via shape shown in FIGS. 2A and 2B is in contrast to the via shape used for interposer and other applications (i.e., vias having vertical sidewalls). Of course, the via shape shown in FIGS. 2A and 2B can be other suitable shapes such as a cylindrical shape (see, e.g., FIG. 2C) or an hourglass shape (see, e.g., FIG. 2D).

The smaller first diameter 202a and 202b at the first surface 108 of the glass substrate 102 enables efficient integration within a crowded pixel layout of a high resolution display. The larger second diameter 204a and 204b at the second surface 110 of the glass substrate 102 enables efficient metallization and relaxation of backside patterning design rules. In general, the structure of vias 200a and 200b allows for the use of smaller via dimensions on the side of the glass substrate requiring precise pixel layout and integration while allowing for larger via dimensions on the side of the glass substrate that benefits more from relaxation of alignment tolerances. Some device designs for display or non-display applications may have the most efficient layouts with the small diameter of the vias on the same substrate surface. Other designs may benefit from having some vias with the smaller diameters on one substrate surface and other vias with the small diameter on the other substrate surface.

Via holes 200a and 200b may be placed, for example, less than about 100, 50, 20, or 10 micrometers away from electronic components other than components used for purely electrical connections. For example, the electronic components may include TFTs, capacitors, inductors, integrated circuits (ICs), or other components. The smaller first diameter 202a and 202b enables this close proximity to the other components.

In certain exemplary embodiments, both via holes 200a and 200b having different dimensions may be formed in a single glass substrate 102, such as in device 100 of FIG. 1. For example, each via of a first portion of the plurality of vias 106 of device 100 may have larger dimensions than each via of a second portion of the plurality of vias 106 of device 100. In other embodiments, a single glass substrate 102 may include three or more via holes having different dimensions. This is in contrast to typical vias within a single substrate in which the vias all have the same dimensions due to the typical laser damage and etch process used where all of the via locations experience similar etching conditions. In this disclosure, however, vias can vary in diameter across the substrate without undergoing a significant increase in process steps since vias with different diameters may be formed on a single substrate at the same formation stage. For example, smaller diameter vias may be formed to carry data signals and larger diameter vias may be formed to carry higher current drive power within in single glass substrate.

FIGS. 3A and 3B are cross-sectional views of exemplary via holes 300a and 300b, respectively. Via holes 300a and 300b each are formed through a glass substrate 102 including a first surface 108 and a second surface 110. Via holes 300a and 300b are tapered from the second surface 110 to the first surface 108 and include curved sidewalls 116b between the first surface 108 and the second surface 110. Via hole 300a includes a first diameter 302a at the first surface 108 and a second diameter 304a greater than the first diameter 302a at the second surface 110. Likewise, via hole 300b includes a first diameter 302b at the first surface 108 and a second diameter 304b greater than the first diameter 302b at the second surface 110. For via hole 300b, however, first diameter 302b and second diameter 304b are greater than first diameter 302a and second diameter 304a of via hole 300a, respectively. In other embodiments, via holes 300a and 300b may have one diameter that is similar for each via hole and another diameter that is different for each via hole. In certain exemplary embodiments, both via holes 300a and 300b may be formed in a single glass substrate 102, such as in device 100 of FIG. 1.

The curved sidewalls 116b may be beneficial during the metallization and via fill process to force bridging of the conductive material to occur at the smaller first diameter 302a and 302b surface. This bridging may naturally create a via pinched at the first surface 108 of the glass substrate 102. The dimensions of first diameters 302a and 302b and second diameters 304a and 304b may be similar to the dimensions of first diameters 202a and 202b and second diameters 204a and 204b, respectively, as previously described with reference to FIGS. 2A and 2B. In certain exemplary embodiments, within a single substrate there may exist vias with different sidewall geometries. For example, linearly tapered, non-linearly tapered, linearly vertical, non-linearly vertical, or other via cross-section geometries with same or differing diameters may exist within the same substrate. These vias may be oriented in the same direction or may also be inversely oriented.

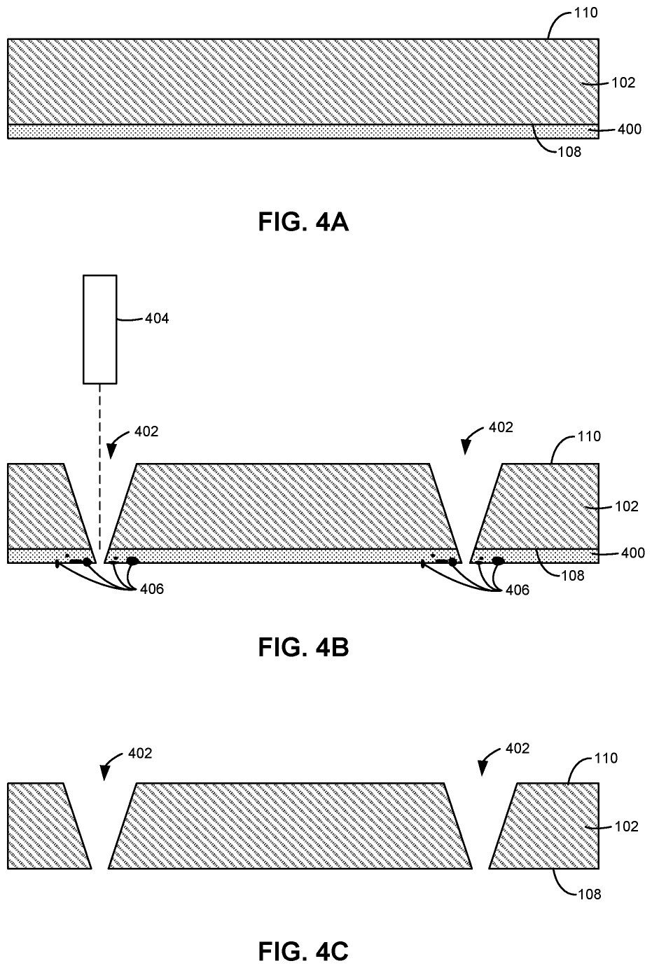

FIGS. 4A-4C are cross-sectional views illustrating an exemplary method for fabricating via holes using a gel layer on one side of a glass substrate. FIG. 4A is a cross-sectional view of a glass substrate 102 and a gel layer 400. Gel layer 400 is applied over the first surface 108 of the glass substrate 102. In certain exemplary embodiments, applying gel layer 400 may include spray coating gel layer 400 to the first surface 108 of the glass substrate 102. In other embodiments, applying gel layer 400 may include spin coating gel layer 400 to the first surface 108 of the glass substrate 102. The gel layer 400 may be applied to a thickness of about 0.5 millimeters or greater. The gel layer 400 provides a temporary protective coating on the first surface 108 of the glass substrate 102 to protect the first surface 108 during a laser ablation process (FIG. 4B). The gel layer 400 acts to collect debris that is created during the laser ablation and minimizes any peak-to-valley edge rim height that may be created around each via during the laser ablation. Although the material is described as a gel, the layer may include alternative materials that are temporarily applied to the substrate that creates a conformal coating.

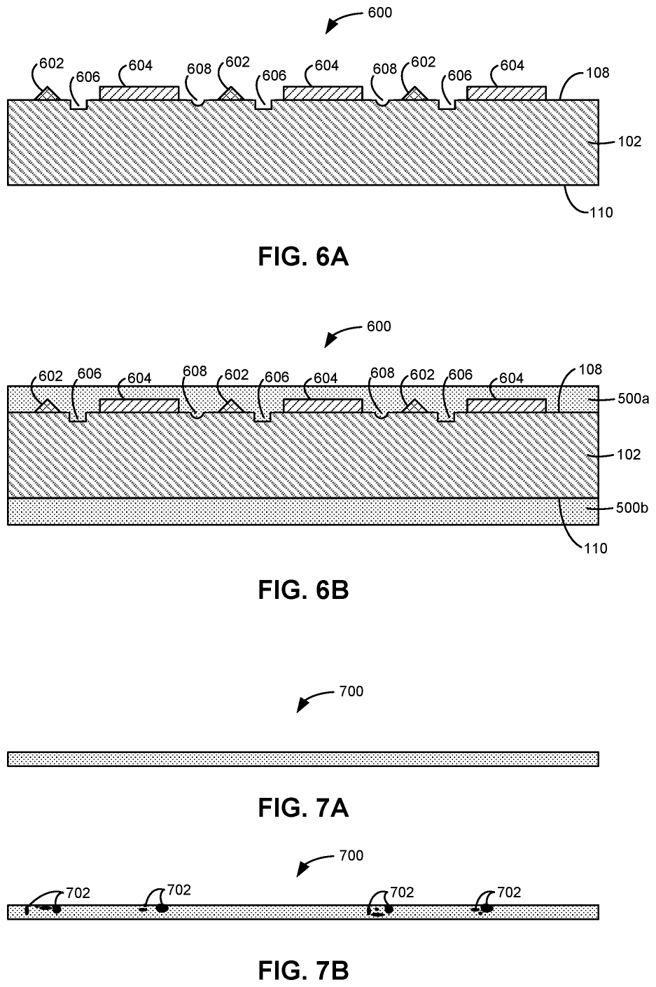

In both gel layer application methods (i.e., spraying and spin coating), a two-step application of materials may be used. For example, in a first step, a layer of a PolyVinyl Alcohol (PVA) solution may be applied to a thickness greater than about 0.5 millimeters to cover the glass substrate. In a second step, a Sodium tetraborate solution may be misted over the PVA. In certain exemplary embodiments, applying gel layer 400 may include applying a layer of a first solution of about 5% to 10% PVA in water by weight and misting a second solution of about 1% to 10% Sodium Tetraborate in water by weight over the layer of the first solution. After the application of gel layer 400, the glass substrate 102 is ready to be laser ablated. Alternatively, if a certain gel layer 400 thickness is desired after application, water may be allowed to evaporate out of the solution to thin the gel layer prior to laser ablation. Forming the gel layer 400 on the glass substrate 102 ensures that there are no air gaps between the gel layer and the glass substrate. In addition, the formation of the gel layer 400 on the glass substrate 102 allows for variable surface conditions. While traditional protective layers need to be applied to a flat surface, gel layer 400 may be applied over all existing structures on the glass substrate 102 such as electronic components or physical features of the glass as will be described in more detail below with reference to FIGS. 6A-6B.

FIG. 4B is a cross-sectional view of the glass substrate 102 and gel layer 400 after laser ablating to form via holes 402. A laser 404 is used to laser ablate the glass substrate 102 to form via holes 402 through the glass substrate 102 such that debris 406 from the laser ablating is trapped in the gel layer 400. The laser ablating is from the second surface 110 of the glass substrate 102 to the first surface 108 to form the via hole including a first diameter at the first surface 108 and a second diameter greater than the first diameter at the second surface 110. In certain embodiments, the ratio between the larger second diameter to the smaller first diameter may, for example, be varied from about 1.5 to about 15. Due to gel layer 400, the debris 406 substantially does not reform onto the glass substrate 102 as described in more detail below. Since the debris 406 does not substantially reform onto the glass substrate 102, the surface of the glass substrate does not become significantly rough so the need for polishing the glass substrate is eliminated or reduced. During laser ablating, the gel of gel layer 400 where the laser is incident is forced out of the way by the laser beam such that the gel does not bond with the glass substrate 102.

If a laser is pulsed and there is no gel layer on the glass substrate, the ablated material reforms on the surface of the glass substrate all around the via hole and even up to millimeters away. The debris may be hot enough such that the debris may attach to the glass substrate surface and become a part of the glass. This debris may be removed by polishing or etching. When a gel layer 400 is on the surface of the glass substrate 102 as depicted in FIG. 4B and the laser is pulsed, instead of the debris reforming onto the first surface 108 of the glass substrate, the debris 406 is substantially trapped inside of the gel layer 400. The debris 406 is kept in the gel layer 400 and does not touch the first surface 108 of the glass substrate 102. In addition to the gel layer 400 collecting the debris, after laser ablating the gel reforms (e.g., the gel is self-healing) onto the first surface 108 of the glass substrate 102 to protect the newly formed via from other debris or by products of the laser damage. Other protective material layers act as a one-time use where once the laser is introduced to that spot, that protective material is also ablated away and cannot protect the newly formed via from additional debris.

When the laser 404 is introduced to the glass substrate 102 without a gel layer and ablates the glass substrate, the laser also melts the surrounding material away from the middle of the via hole. Internally, this melting causes a localized compaction of the glass substrate and towards the openings of the via hole the material is pushed up and away from the glass substrate forming a rim that can be micrometers in scale. With the addition of the gel layer 400, the rim formation does not occur on the first surface 108 of the glass substrate 102 or occurs at a much reduced level. This helps maintain the surface quality of the glass substrate 102 so that the vias can be reached for a multitude of uses without having a barrier due to the rim.

The laser ablation may be performed with a single laser 404 (e.g., CO₂ laser) to create the tapered structure without the need for significant etching. An etch process may still be used as a clean-up step to complete the via formation if desired. The elimination of the significant etching step drastically reduces the overall process time and cost associated with the via formation, especially for display applications that may have fewer vias per substrate compared to other applications. Elimination or substantial reduction of the via etch step while incurring a small increase in laser processing per via is a trade-off that increases the overall process throughput.

The via holes 402 may be formed in the glass substrate 102 before substantial electronic processing, at the end of the device fabrication process, or in the middle of the device fabrication process. Location of the via formation process depends upon the specific process step requirements that may occur before or after via formation. As part of the processing, the temporary protective gel layer 400 may be applied at any step before via hole formation and removed at any step after via hole formation. In addition, the via hole formation can create a blind via hole structure. In this case, the via hole is mostly created and then the final opening or connection on the smaller diameter side is formed at a later step. This final opening may be created by an etch process. If it is controlled by a photolithographically patterned etch process, the location of the smaller diameter via opening may be very precisely controlled to enable integration within a pixel. This small etched opening may also be created before the laser ablation process.

Laser 404 may, for example, include various mirrors and a lens (e.g., 1, 2, or 4 inch lens). Laser 404 may form via holes 402 having an upper diameter (i.e., at second surface 110) between about 150 and 250 micrometers and a lower diameter (i.e., at first surface 108) between about 10 and 150 micrometers. In certain exemplary embodiments, an xyz stage (not shown) may be used to move glass substrate 102 relative to laser 404. Laser 404, for example, may have a 5.5, 9.3, or 10.6 micrometers wavelength. Laser 404 may, for example, be a 30 watt laser to provide hundreds of 50 microsecond pulses in a 200 microsecond waveform to form each via hole 402. Laser 404 may also be an 80 watt laser to provide 27 microsecond pulses in a 280 microsecond waveform to form each via hole 402. In other embodiments, other laser powers and waveforms may be used to form each via hole 402 by providing a pulse train to ablate through holes in about 15 milliseconds or less. The laser beam is not hindered by the gel layer 400.

FIG. 4C is a cross-sectional view of the glass substrate 102 after removal of the gel layer 400. Gel layer 400 is removed from the first surface 108 of the glass substrate 102. After the glass substrate 102 is processed by the laser, the gel layer 400 is still intact and contains the debris 406. When the gel layer 400 is to be removed, the gel layer may be removed using any suitable process. One way to remove gel layer 400 is by peeling off the gel layer and leaving a clean surface behind. Another way to remove gel layer 400 is by dissolving the gel layer in water or in water and a surfactant cleaner solution. Both of these methods will leave the first surface 108 of the glass substrate 102 free of debris. After removal of the gel layer 400, if desired, the gel layer may be placed onto another substrate and reused rather than being discarded. Multiple uses of the gel layer may reduce costs and save on the cost of materials. To reuse the gel layer 400, the gel layer may be peeled off of one substrate and placed onto another substrate and a small amount of force may be applied to stick the gel layer to the substrate.

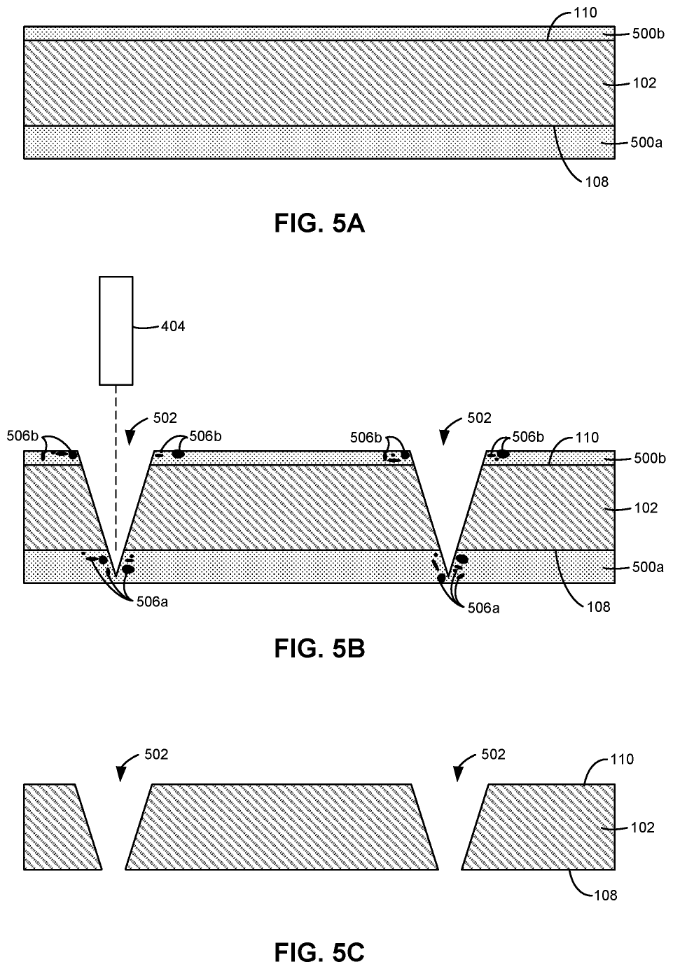

FIGS. 5A-5C are cross-sectional views illustrating an exemplary method for fabricating via holes using a gel layer on both sides of a glass substrate. FIG. 5A is a cross-sectional view of a glass substrate 102, a first gel layer 500a, and a second gel layer 500b. First gel layer 500a is applied over the first surface 108 of the glass substrate 102. Second gel layer 500b is applied over the second surface 110 of the glass substrate 102. In certain exemplary embodiments, applying each gel layer 500a and 500b may include spray coating first gel layer 500a to the first surface 108 of the glass substrate 102 and spray coating second gel layer 500b to the second surface 110 of the glass substrate 102. In other embodiments, applying each gel layer 500a and 500b may include spin coating first gel layer 500a to the first surface 108 of the glass substrate 102 and spin coating second gel layer 500b to the second surface 110 of the glass substrate 102.

Applying each gel layer 500a and 500b may, for example, include applying a layer of a first solution of 5% to 10% PolyVinyl Alcohol (PVA) in water by weight and misting a second solution of 1% to 10% Sodium Tetraborate in water by weight over the layer of the first solution for each gel layer 500a and 500b. The first gel layer 500a and the second gel layer 500b may, for example, both be applied to a thickness of about 0.5 millimeters or greater. The gel layers 500a and 500b provide a temporary protective coating on first surface 108 and second surface 110 of the glass substrate 102 to protect the first surface 108 and the second surface 110, respectively, during a laser ablation process (FIG. 5B). The gel layers 500a and 500b act to collect debris that is created during the laser ablation and minimize any peak-to-valley edge rim height that may be created around each via during the laser ablation. For example, if the gel layer is not used, the peak-to-valley edge rim height (i.e., top of rim to substrate surface) may be greater than about 1, 5, 10, or 30 micrometers. By using the gel layer during laser ablation, the peak-to-valley edge rim height may, for example, be less than about 1, 0.5, 0.1, 0.05, or 0.02 micrometers. By using the gel during laser ablation, the peak-to-valley edge rim height may, for example, be within a range of 1-500, 2-100, or 5-20 nanometers.

FIG. 5B is a cross-sectional view of glass substrate 102, first gel layer 500a, and second gel layer 500b after laser ablating to form via holes 502. A laser 404 is used to laser ablate the glass substrate 102 to form via holes 502 through the glass substrate 102 such that debris 506a from the laser ablating is trapped in the first gel layer 500a and debris 506b from the laser ablating is trapped in the second gel layer 500b. The laser ablating is from the second surface 110 of the glass substrate 102 to the first surface 108 to form the via hole including a first diameter at the first surface 108 and a second diameter greater than the first diameter at the second surface 110. First gel layer 500a and second gel layer 500b also substantially prevent the formation of a rim around each via 502 on the first surface 108 and on the second surface 110, respectively.

FIG. 5C is a cross-sectional view of the glass substrate 102 after removal of the first gel layer 500a and the second gel layer 500b. First gel layer 500a is removed from the first surface 108 of the glass substrate 102, and second gel layer 500b is removed from the second surface 110 of the glass substrate 102. Each gel layer 500a and 500b may, for example, be removed by peeling the gel layer from the first surface 108 and the second surface 110, respectively, or by washing (e.g., with water) the glass substrate 102 to dissolve the gel layers 500a and 500b as previously described above with reference to FIG. 4C.

FIGS. 6A and 6B are cross-sectional views illustrating an exemplary method for fabricating components on a glass substrate prior to applying a gel layer on both sides of the glass substrate. FIG. 6A is a cross-sectional view of an apparatus 600. Apparatus 600 includes a glass substrate 102 with electronic components 602 and 604 and glass features 606 and 608 on the first surface 108 of the glass substrate 102. Electronic components 602 and 604 and glass features 606 and 608 may be fabricated on the first surface 108 of the glass substrate 102 prior to applying the first gel layer 500a or the second gel layer 500b of FIG. 5.

FIG. 6B is a cross-sectional view of the apparatus 600 of FIG. 6A with the first gel layer 500a and the second gel layer 500b applied. The first gel layer 500a is applied over the first surface 108 of the glass substrate 102 and covers electronic components 602 and 604 and glass features 606 and 608. Therefore, electronic components 602 and 604 and glass features 606 and 608 are protected from debris during laser ablation. The second gel layer 500b is applied over the second surface 110 of the glass substrate 102. Apparatus 600 may then be processed by laser 404 as previously described and illustrated with reference to FIG. 5B to form via holes.

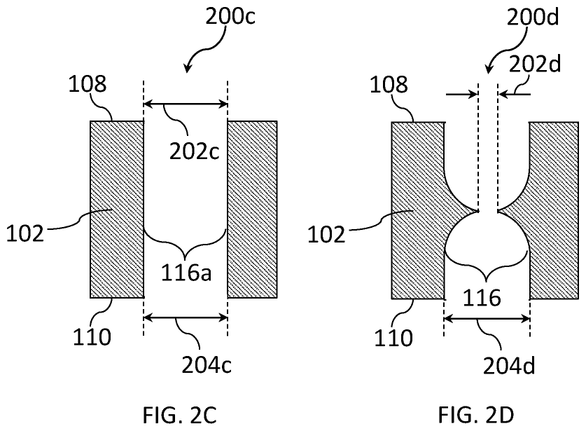

FIG. 7A is a cross-sectional view of an exemplary material 700 for collecting debris due to laser ablation prior to use. Material 700 may include a first solution of 5% to 10% PolyVinyl Alcohol (PVA) in water by weight and a second solution of 1% to 10% Sodium Tetraborate in water by weight. Material 700 may have a viscosity between 60,000 and 140,000 npoise. In other embodiments, material 700 may be made of other solutions having a similar viscosity. Material 700 may be in the form of a tacky sheet as shown in FIG. 7A to attach to a substrate (e.g., glass substrate 102 previously described) to be laser ablated.

The composition of material 700 is inexpensive and toxic-free. Since the material 700 is a non-newtonian solid, the material may be peeled off the substrate after use. By being made of an ion and polymer that are both soluble in water, material 700 also allows for easy cleaning if there is any residue left on the substrate after the gel is removed by washing with water.

FIG. 7B is a cross-sectional view of the exemplary material 700 after use wherein debris 702 is trapped within material 700. The tacky sheet of material 700 is reusable, such that material 700 may by attached to a further substrate to be laser ablated to collect additional debris during laser ablating of the further substrate. By using material 700 for laser ablating via holes in a glass substrate, no post chemical etching is needed. The material is easily applied to a substrate and easily removed by peeling off the material after the laser ablation. The material may be applied over preexisting surface features and conform to their shapes. The material collects debris from the laser ablation, thus resulting in a debris-free surface. In addition, rim formation around the via holes is significantly reduced. By using material 700, the process for forming via holes is low cost and fast and has a simple and inexpensive setup. Finally, the via formation process disclosed herein using material 700 may be used for different glass types and applications.

It will be apparent to those skilled in the art that various modifications and variations can be made to embodiments of the present disclosure without departing from the spirit and scope of the disclosure. Thus it is intended that the present disclosure cover such modifications and variations provided they come within the scope of the appended claims and their equivalents.

What is claimed is:

1. A device comprising:
a glass substrate;
a plurality of electronic components on a first surface of the glass substrate;
a metallization layer on a second surface of the glass substrate opposite to the first surface; and
a plurality of vias extending through the glass substrate, at least one via in electrical communication with an electronic component and the metallization layer,
wherein at least one via comprises a first diameter at the first surface and a second diameter greater than the first diameter at the second surface such that a ratio of the second diameter to the first diameter is greater than 1.5:1.

2. The device of claim 1, wherein at least one of the vias is tapered from the second surface to the first surface.

3. The device of claim 2, wherein the at least one tapered via comprises linear sidewalls between the first surface and the second surface.

4. The device of claim 2, wherein the at least one tapered via comprises curved sidewalls between the first surface and the second surface.

5. The device of claim 1, wherein at least one of the vias comprises a conformal conductive layer on sidewalls of the via.

6. The device of claim 5, wherein at least one of the vias is at least partially filled with an insulating, conductive, or semi-conductive material.

7. The device of claim 6, wherein the insulative, conductive, or semi-conductive material is selected from at least one of a sol-gel, glass, or glass ceramic material.

8. The device of any claim 1, wherein each via of a first portion of the plurality of vias comprises larger dimensions than each via of a second portion of the plurality of vias.

9. The device of any claim 1, wherein the device comprises a display and the plurality of electronic components comprise a plurality of thin-film transistors.

10. A method for fabricating vias, the method comprising:
applying a first gel layer over a first surface of a glass substrate;
laser ablating the glass substrate to form a via hole through the glass substrate such that debris from the laser ablating is trapped in the first gel layer; and
removing the first gel layer from the first surface.

11. The method of claim 10, further comprising:
applying a second gel layer over a second surface of the glass substrate opposite to the first surface prior to the laser ablating; and
removing the second gel layer from the second surface after the laser ablating,
wherein the laser ablating comprises laser ablating the glass substrate to form the via hole through the glass substrate such that debris from the laser ablating is trapped in the first gel layer and the second gel layer.

12. The method of claim 10, wherein the laser ablating is from a second surface of the glass substrate to the first surface to form the via hole comprising a first diameter at the first surface and a second diameter greater than the first diameter at the second surface.

13. The method of claim 10, wherein the laser ablating is from the first surface to a second surface of the glass substrate to form the via hole such that the first gel layer reduces the formation of a rim around the via on the first surface.

14. The method of claim 10, wherein applying the first gel layer comprises spray coating the first gel layer to the first surface of the glass substrate.

15. The method of claim 10, wherein applying the first gel layer comprises spin coating the first gel layer to the first surface of the glass substrate.

16. The method of claim 10, further comprising:
fabricating electronic components on the first surface prior to applying the first gel layer.

17. The method of claim 10, wherein applying the first gel layer comprises applying a layer of a first solution of 5% to 10% PolyVinyl Alcohol (PVA) in water by weight and misting a second solution of 1% to 10% Sodium Tetraborate in water by weight over the layer of the first solution.

18. A material for collecting debris due to laser ablation, the material comprising:
a first solution of 5% to 10% PolyVinyl Alcohol (PVA) in water by weight; and
a second solution of 1% to 10% Sodium Tetraborate in water by weight.

19. The material of claim 18, wherein the material comprises a viscosity between 60,000 and 140,000 npoise.

20. The material of claim 18, wherein the material is in the form of a tacky sheet to attach to a substrate to be laser ablated.

21. The material of claim 20, wherein the tacky sheet is reusable.

22. A device comprising:
a glass substrate;
a plurality of electronic components on a first surface of the glass substrate;
a metallization layer on a second surface of the glass substrate opposite to the first surface; and
a plurality of vias extending through the glass substrate, at least one via in electrical communication with an electronic component and the metallization layer,
wherein at least one via is at least partially filled with an insulating, conductive, or semi-conductive material.

23. The device of claim 22, wherein the insulative, conductive, or semi-conductive material is selected from at least one of a sol-gel, glass, or glass ceramic material.
